(19) United States
(12) Patent Application Publication
(10) Pub. No.: US 2025/0087505 A1
(43) Pub. Date: Mar. 13, 2025

(54) MICROWAVE ANNEALING FOR LOW THERMAL BUDGET APPLICATIONS

(71) Applicant: Applied Materials, Inc., Santa Clara, CA (US)

(72) Inventors: Shashank Sharma, Fremont, CA (US); Wolfgang Robert Aderhold, Cupertino, CA (US); Vikash Banthia, Los Altos, CA (US)

(21) Appl. No.: 18/367,321

(22) Filed: Sep. 12, 2023

(51) Int. Cl. H01L 21/67; H01L 21/324; H01L 21/683

(52) U.S. Cl. CPC H01L 21/67115; H01L 21/324; H01L 21/67248; H01L 21/6831

(57) ABSTRACT

A system includes a chamber body defining a processing volume. The system further includes a substrate support pedestal positioned in the processing volume and operable to support a substrate, the substrate support pedestal including one or more channels, where a coolant medium flows through the one or more channels to facilitate heat transfer from the substrate to the coolant medium. The system further includes a coolant medium circulator to circulate the coolant medium through the one or more channels. The system further includes a substrate temperature sensor operatively coupled to the chamber body, where the substrate temperature sensor measures a temperature of the substrate. The system further includes a coolant medium circulation controller, coupled to the coolant medium circulator and the substrate temperature sensor, to control a rate at which the coolant medium is circulated through the one or more channels.

### TECHNICAL FIELD

The present disclosure generally relates to systems and methods for manufacturing a semiconductor device. More particularly, the present disclosure generally relates to a system and a method for thermally processing a substrate.

### BACKGROUND

Substrate processing can utilize operations that output large amounts of heat that can damage semiconductor devices during manufacture. By removing heat from substrates undergoing a microwave annealing process in a processing chamber (e.g., a microwave annealing processing chamber), damage due to heat can be mitigated, while realizing the beneficial effects of microwave energy on device features.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In one aspect of the disclosure, a system for implementing methods such as those discussed below is disclosed. The system includes a chamber body defining a processing volume. The system further includes a substrate support pedestal positioned in the processing volume and operable to support a substrate, the substrate support pedestal including one or more channels, where a coolant medium flows through the one or more channels to facilitate heat transfer from the substrate to the coolant medium. The system further includes a coolant medium circulator to circulate the coolant medium through the one or more channels. The system further includes a substrate temperature sensor operatively coupled to the chamber body, where the substrate temperature sensor measures a temperature of the substrate. The system further includes a coolant medium circulation controller, coupled to the coolant medium circulator and the substrate temperature sensor, to control a rate at which the coolant medium is circulated through the one or more channels.

In another aspect of the disclosure, a method includes determining, by a coolant medium circulation controller, a microwave power value of a microwave annealing operation, the microwave annealing operation being performed on a substrate supported by a substrate support pedestal positioned within a processing volume defined by a chamber body. The method further includes causing, by the coolant medium circulation controller, a coolant medium to flow at a coolant medium flow rate through at least one channel disposed within the substrate support pedestal.

In another aspect of the disclosure, a method includes determining, by a coolant medium circulation controller, a temperature of a substrate supported by a substrate support pedestal positioned within a processing volume defined by a chamber body, the substrate undergoing a microwave annealing operation. The method further includes changing, by the coolant medium circulation controller, a first coolant medium flow rate for a coolant medium flowing through at least one channel disposed within the substrate support pedestal to a second coolant medium flow rate based on the temperature of the substrate.

### BRIEF DESCRIPTION OF THE DRAWINGS

The present disclosure is illustrated by way of example, and not by way of limitation in the figures of the accompanying drawings.

FIG. 1 is a top schematic view of an example electronic device manufacturing system, in accordance with some embodiments.

FIG. 2 is a cross-sectional view of a processing chamber (e.g., a semiconductor wafer processing chamber) according to some embodiments.

FIGS. 3A-B are flow diagrams of a methods associated with microwave annealing for low thermal budget applications, according to certain embodiments.

FIG. 4 is a block diagram illustrating a computer system, according to certain embodiments.

### DETAILED DESCRIPTION

Described herein are technologies directed to microwave annealing for low thermal budget applications. Manufacturing equipment is used to produce substrates, such as semiconductor wafers. The properties of these substrates are controlled by the conditions under which the substrates were processed.

The importance of defects in semiconductor materials, such as single crystalline silicon, is generally recognized with respect to the physical, optical and electronic properties of these materials. Diffusion rates of dopants during annealing processing, for example, have been demonstrated to depend significantly on the type and abundance of defects, such as interstitials and vacancies, in implanted silicon. In addition, the presence of defects in bulk semiconductor materials has been shown to impact other physical properties such as current flow in integrated circuit (IC) devices and the performance of photoactive devices and gas sensors. Defects provide sites where electrons and holes recombine with enhanced efficiency, for example, which is understood to degrade the performance of host materials.

During annealing, a substrate is typically heated to high temperatures so that various chemical and physical reactions can take place in multiple IC devices defined in the substrate. Annealing recreates a more crystalline structure from regions of the substrate that were previously made amorphous, and “activates” dopants by incorporating their atoms into the crystalline lattice of the substrate. Ordering the crystal lattice and activating dopants reduces resistivity of the doped regions. Thermal processes, such as annealing, involve directing a relatively large amount of thermal energy onto a substrate in a short amount of time, and thereafter rapidly cooling the substrate to terminate the thermal process. It is important to note that annealing is used for removing defects and impurities caused by ion-implantation on and near the surface of the wafer. Similarly, annealing is commonly used at junctions and contact regions near the surface of the wafer. Annealing helps to refine these features, reduce defects, and enhance the electrical properties and conductivity at these critical regions. Heating the entire wafer uniformly can lead to potential damage in areas where the annealing effects are not desired.

Examples of thermal processes that have been widely used for some time include Rapid Thermal Processing (RTP) and impulse (spike) annealing. Although widely used, such processes may not be ideal because these processes raise the bulk temperature of the wafer too much which in turn exposes certain regions of the wafer to high temperatures. Such regions may not require or should not be exposed to high temperatures because of the possibility of damage from exposure. Such processes lack temperature control over those certain regions of the wafer that are sensitive to excessive heat. This in turn leads to damaged wafers, which can be costly in terms of time expended, material used, etc. These problems become more severe with increasing processing temperatures, increasing wafer size, and/or decreasing feature sizes.

For the foregoing reasons, there is a need for improved systems and methods for low thermal budget annealing of semiconductor substrates.

Aspects and implementations of the present disclosure address these and other shortcomings of the existing technology by implementing a system and methods for low thermal budget annealing of semiconductor substrates. The present disclosure provides low thermal budget annealing solutions utilizing microwave radiation. Microwave energy absorption in semiconductor device wafers can raise the wafer temperature. The increase in wafer temperature may be proportionate to the amount of microwave energy absorbed. The present disclosure provides solutions that include independent wafer temperature control during microwave annealing by cooling the substrate. The solutions include a system and methods for microwave annealing for low thermal budget applications.

The system includes a chamber body defining a processing volume, a substrate support pedestal positioned in the processing volume and operable to support a substrate. The substrate support pedestal includes one or more channels, where a coolant medium flows through the one or more channels to facilitate heat transfer from the substrate to the coolant medium. The system further includes a coolant medium circulator to circulate the coolant medium through the one or more channels. The system further includes a substrate temperature sensor operatively coupled to the chamber body, where the substrate temperature sensor measures a temperature of the substrate. The system further includes a coolant medium circulation controller, coupled to the coolant medium circulator and the substrate temperature sensor, to control a rate at which the coolant medium is circulated through the one or more channels.

In some embodiments, the substrate receives microwaves during a microwave annealing operation. In some embodiments, a wavelength of the microwaves of the microwave annealing operation ranges from two gigahertz to seven gigahertz.

In some embodiments, the coolant medium circulation controller determines the rate at which the coolant medium is circulated based on a substrate support temperature setpoint and a closed loop control. In some embodiments, the closed loop control includes the substrate temperature sensor, the coolant medium circulation controller, and the coolant medium circulator.

In some embodiments, the coolant medium circulation controller determines the rate at which the coolant medium is circulated by using a look-up table. In some embodiments, the look-up table includes input key values each corresponding to a respective microwave power value and output values each corresponding to a respective coolant medium flow rate.

In some embodiments, the look-up table includes input key value pairs and output values. In some embodiments, each of the input key value pairs corresponds to a respective microwave power value and a respective ambient gas type in the processing volume. In some embodiments, the output values each correspond to a respective coolant medium flow rate. In some embodiments, the respective microwave power value ranges from 100 watts to 20 kilowatts and the respective ambient gas type is at least one of helium, nitrogen, oxygen, argon, carbon dioxide, carbon monoxide, ammonia, hydrogen sulfide, fluorine, or chlorine. In some embodiments, the coolant medium is at least one of water, liquid nitrogen, liquid helium, liquid argon, liquid oxygen, liquid neon, liquid xenon, liquid krypton, liquid carbon dioxide, liquid propane, liquid methane, ethanol, liquid freon, or liquid ethylene.

In some embodiments, the substrate support pedestal leaves a significant portion of a surface area of the substrate exposed to the processing volume, and a gas is circulated within the processing volume to cool the substrate.

Aspects and implementations of the present disclosure results in technological advantages. Aspects of the present disclosure provide the ability to regulate the bulk temperature of a substrate undergoing a microwave annealing process allows the regions on and near the surface of the substrate to be heated while the bulk temperature remains lower. This affords a microwave annealing system enhanced temperature control over those certain regions of the wafer that are sensitive to excessive heat, leading to less damaged wafers, savings in terms of time expended, material used, etc.

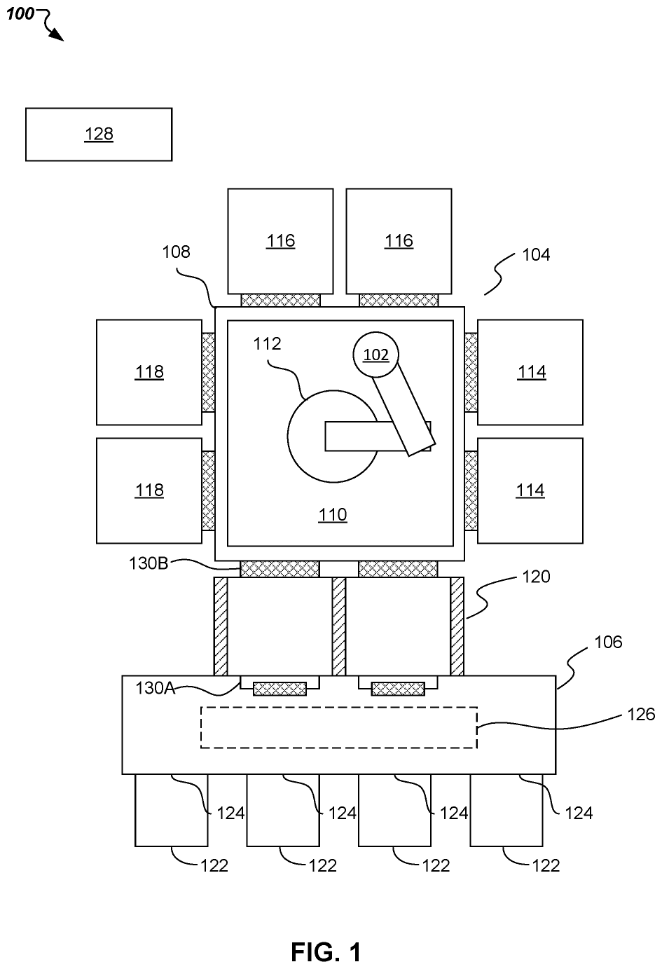

FIG. 1 is a top schematic view of an example electronic device manufacturing system 100, according to aspects of the present disclosure. It is noted that FIG. 1 is used for illustrative purposes, and that different component can be positioned in different location in relation to each view. In some embodiments, system 100 includes multiple processing chambers (e.g., for microwave annealing for low thermal budget applications).

Electronic device manufacturing system 100 (also referred to as an electronics processing system) is configured to perform one or more processes on a substrate 102. Substrate 102 can be any suitably rigid, fixed-dimension, planar article, such as, e.g., a silicon-containing disc or wafer, a patterned wafer, a glass plate, or the like, suitable for fabricating electronic devices or circuit components thereon.

Electronic device manufacturing system 100 includes a process tool 104 (e.g., a mainframe) and a factory interface 106 (e.g., an EFEM) coupled to process tool 104. Process tool 104 includes a housing 108 having a transfer chamber 110 therein. Transfer chamber 110 includes one or more processing chambers (also referred to as process chambers) 114, 116, 118 disposed therearound and coupled thereto. Processing chambers 114, 116, 118 can be coupled to transfer chamber 110 through respective ports, such as slit valves or the like.

Processing chambers 114, 116, 118 can be adapted to carry out any number of processes on substrates 102. A same or different substrate process can take place in each processing chamber 114, 116, 118. Examples of substrate processes include annealing (e.g., microwave annealing for low thermal budget applications), atomic layer deposition (ALD), physical vapor deposition (PVD), chemical vapor deposition (CVD), etching, curing, pre-cleaning, metal or metal oxide removal, or the like. In one example, a PVD process is performed in one or both of process chambers 114, an etching process is performed in one or both of process chambers 116, and an annealing process is performed in one or both of process chambers 118. Other processes can be carried out on substrates therein. Processing chambers 114, 116, 118 can each include a substrate support assembly. The substrate support assembly can be configured to hold a substrate in place while a substrate process is performed.

Transfer chamber 110 also includes a transfer chamber robot 112. Transfer chamber robot 112 can include one or multiple arms where each arm includes one or more end effectors at the end of each arm. The end effector can be configured to handle particular objects, such as wafers. Alternatively, or additionally, the end effector is configured to handle objects such as process kit rings. In some embodiments, transfer chamber robot 112 is a selective compliance assembly robot arm (SCARA) robot, such as a 2-link SCARA robot, a 3-link SCARA robot, a 4-link SCARA robot, and so on.

A load lock 120 can also be coupled to housing 108 and transfer chamber 110. Load lock 120 can be configured to interface with, and be coupled to, transfer chamber 110 on one side and factory interface 106 on another side. Load lock 120 can have an environmentally-controlled atmosphere that is changed from a vacuum environment (where substrates are transferred to and from transfer chamber 110) to an at or near atmospheric-pressure inert-gas environment (where substrates are transferred to and from factory interface 106) in some embodiments. In some embodiments, load lock 120 is a stacked load lock having a pair of upper interior chambers and a pair of lower interior chambers that are located at different vertical levels (e.g., one above another). In some embodiments, the pair of upper interior chambers are configured to receive processed substrates from transfer chamber 110 for removal from process tool 104, while the pair of lower interior chambers are configured to receive substrates from factory interface 106 for processing in process tool 104. In some embodiments, load lock 120 is configured to perform a substrate process (e.g., an etch or a pre-clean) on one or more substrates 102 received therein.

Factory interface 106 can be any suitable enclosure, such as, e.g., an Equipment Front End Module (EFEM). Factory interface 106 can be configured to receive substrates 102 from substrate carriers 122 (e.g., Front Opening Unified Pods (FOUPs)) docked at various load ports 124 of factory interface 106. A factory interface robot 126 (shown dotted) can be configured to transfer substrates 102 between substrate carriers 122 (also referred to as containers) and load lock 120. In other and/or similar embodiments, factory interface 106 is configured to receive replacement parts from replacement parts storage containers. Factory interface robot 126 can include one or more robot arms and can be or include a SCARA robot. In some embodiments, factory interface robot 126 has more links and/or more degrees of freedom than transfer chamber robot 112. Factory interface robot 126 can include an end effector on an end of each robot arm. The end effector can be configured to pick up and handle specific objects, such as wafers. Alternatively, or additionally, the end effector can be configured to handle objects such as process kit rings. Any conventional robot type can be used for factory interface robot 126. Transfers can be carried out in any order or direction. Factory interface 106 can be maintained in, e.g., a slightly positive-pressure non-reactive gas environment (using, e.g., nitrogen, other inert gasses, or air with controlled sub-component parameters as the non-reactive gas) in some embodiments.

Factory interface 106 can be configured with any number of load ports 124, which can be located at one or more sides of the factory interface 106 and at the same or different elevations.

Factory interface 106 can include one or more auxiliary components (not shown). The auxiliary components can include substrate storage containers, metrology equipment, servers, air conditioning units, etc. A substrate storage container can store substrates and/or substrate carriers (e.g., FOUPs), for example. Metrology equipment can be used to determine property data of the products that were produced by the electronic device manufacturing system 100. In some embodiments, factory interface 106 can include an upper compartment. The upper compartment can house electronic systems (e.g., servers, air conditioning units, etc.), utility cables, system controller 128, or other components. In some embodiments, the electronic systems, utility cables, etc. housed in the upper compartment include a processing chamber for microwave annealing for low thermal budget applications as described herein.

In some embodiments, transfer chamber 110, process chambers 114, 116, and 118, and/or load lock 120 are maintained at a vacuum level. Electronics processing system 100 can include one or more vacuum ports that are coupled to one or more stations of electronic device manufacturing system 100. For example, first vacuum ports 130A can couple factory interface 106 to load locks 120. Second vacuum ports 130B can be coupled to load locks 120 and disposed between load locks 120 and transfer chamber 110.

Electronic device manufacturing system 100 can also include a system controller 128. System controller 128 can be and/or include a computing device such as a personal computer, a server computer, a programmable logic controller (PLC), a microcontroller, and so on. System controller 128 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 128 can include a data storage device (e.g., one or more disk drives and/or solid-state drives), a main memory, a static memory, a network interface, and/or other components. System controller 128 can execute instructions to perform any one or more of the methodologies and/or embodiments described herein. The instructions can be stored on a computer readable storage medium, which can include the main memory, static memory, secondary storage and/or processing device (during execution of the instructions). System controller 128 can include an environmental controller configured to control an environment (e.g., gas pressure, moisture level, vacuum level, etc.) within factory interface 106. System controller 128 can also be configured to permit entry and display of data, operating commands, and the like by a human operator.

In some embodiments, system controller 128 may be coupled with other components of system 100 (e.g., process chambers 114, 116, and 118, transfer chamber 110, transfer chamber robot 112, etc.) via any suitable connection type. For example, system controller 128 may be coupled with process chamber 118 and subcomponents of process chamber 118 (e.g., a substrate temperature sensor of, a coolant medium circulation controller of process chamber 118, a coolant medium circulator of process chamber 118, etc.) via a network (e.g., local area network (LAN), wide area network (WAN), etc.), a bus connection (e.g., a shared data bus, a serial bus, etc.), a wireless connection (e.g., via Wi-Fi, Bluetooth, etc.), a direct connection (e.g., wired connection), an optical connection, an RF connection, and/or the like.

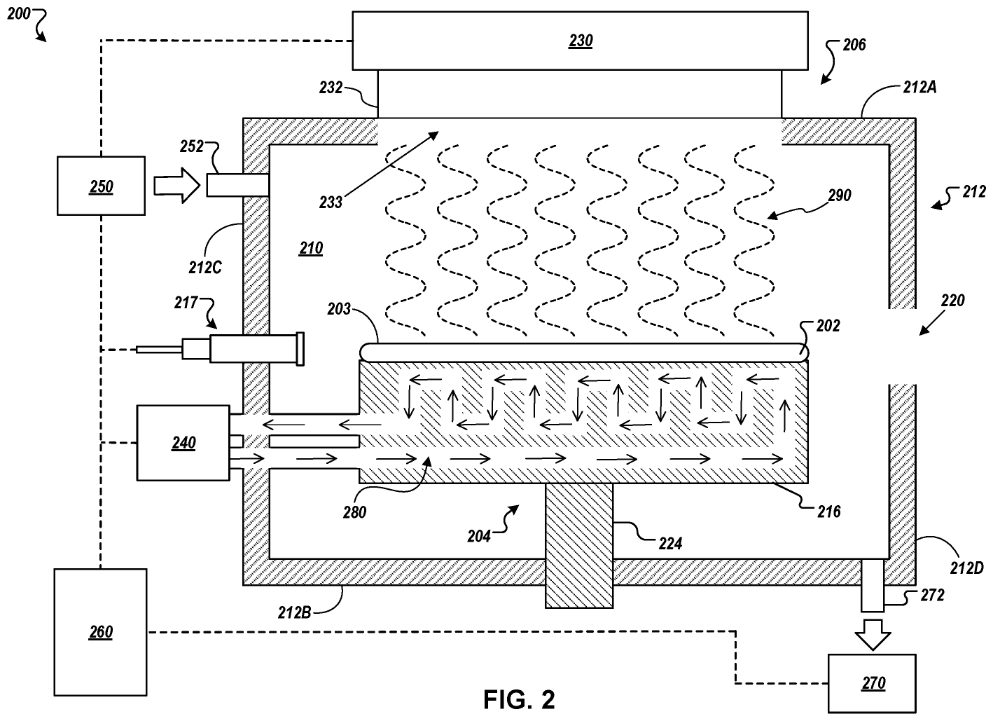

FIG. 2 is a cross-sectional view of a processing chamber (e.g., a semiconductor wafer processing chamber) according to some embodiments. In some embodiments, a processing system 200 includes an electromagnetic energy source 230, which may be a continuous source. In some embodiments, electromagnetic energy source 230 may be a microwave energy source. The processing system 200 may be a semiconductor processing system, for example, an annealing system (e.g., a microwave annealing system for low thermal budget applications). The processing system 200 may be used to perform microwave annealing for low thermal budget applications as described herein. The processing system 200 includes a processing chamber 206.

The processing chamber 206 includes a chamber body 212. The chamber body 212 at least partially defines a processing volume 210. In some embodiments, the chamber body 212 includes a top wall 212A (e.g., a ceiling or lid), a bottom wall 212B (e.g., a floor) opposite the top wall 212A, a first sidewall 212C coupling the top wall 212A and the bottom wall 212B, and a second sidewall 212D opposite the first sidewall 212C. The chamber body 212 may be or include any material suitable with the processes performed in the processing chamber 206. For example, suitable materials fort the chamber body 212 include aluminum, stainless steel, ceramic materials, or a combination thereof.

At least one substrate support pedestal 216 is disposed in the processing volume 210 to support one or more substrate(s) 202 thereupon during processing. In some embodiments, a substrate support assembly 204 includes substrate support pedestal 216 and shaft 224. Substrate support assembly 204 supports a substrate during processing (e.g., microwave annealing processing for low thermal budget applications). The substrate(s) 202 can be brought into the processing volume 210 through a loading port 220. The substrate(s) 202 can include a major surface 203 on which devices and/or deposition takes place. The substrate support pedestal 216 may be any support pedestal for holding one or more semiconductor substrates and may include such components as an electrostatic chuck, clamps, edge rings, guide pins, or the like for physically locating and retaining the substrate. In some embodiments, the substrate support pedestal 216 is configured for rotation during processing. In some embodiments, the substrate support pedestal 216 includes one or more channel(s) 280 for the circulation of a coolant medium through substrate support pedestal 216 to facilitate heat transfer from substrate(s) 202.

In some embodiments, the processing system 200 further includes a coolant medium circulator 240. In some embodiments, the coolant medium circulator 240 circulates the coolant medium through the one or more channel(s) 280.

The processing system 200 may further include a coolant medium circulation controller 260. In some embodiments, coolant medium circulator 240 is coupled to coolant medium circulation controller 260 (e.g., via a direct physical connection). In some embodiments, coolant medium circulator 240 is controlled by coolant medium circulation controller 260.

In some embodiments, the processing system 200 further includes a substrate temperature sensor 217. The substrate temperature sensor 217 may be embedded in the chamber body 212, substrate support pedestal 216, and/or in any other suitable location. In some embodiments, the substrate temperature sensor 217 is coupled to the coolant medium circulation controller 260. In some embodiments, the substrate temperature sensor 217 measures the temperature of substrate(s) 202 and sends the temperature measurement to a hub/data processing unit (not pictured) which is connected to coolant medium circulation controller 260. Coolant medium circulation controller 260 determines, based on the temperature measurement, a coolant medium flow rate and causes the coolant medium circulator 240 to circulate the coolant medium at the determined coolant medium flow rate. In some embodiments, substrate temperature sensor 217 may be a pyrometer. In some embodiments, the substrate temperature sensor may be any suitable temperature sensor. For example, the substrate temperature sensor may be at least one of a thermocouple, resistance temperature detector, thermistor, infrared temperature sensor, semiconductor temperature sensor, fiber optic temperature sensor, etc.

In some embodiments, a substrate support temperature setpoint and a closed loop control are used to determine the coolant medium flow rate. In some embodiments, the closed loop control includes the substrate temperature sensor 217, coolant medium circulation controller 260, and coolant medium circulator 240. In some embodiments, the substrate temperature is monitored by the substrate temperature sensor 217 is used by the coolant medium circulation controller 260 to determine the operation of the coolant medium circulator 240. In some embodiments, the coolant medium circulation controller 260 controls the coolant medium circulator 240 in response to the monitored substrate temperature.

During a manufacturing process (e.g., microwave annealing for low thermal budget applications), conditions in processing chamber 206 are monitored by sensors (e.g., temperature sensor 217). Data indicative of measurements made by the sensor may be provided to coolant medium circulation controller 260.

The processing system 200 further includes the electromagnetic energy source 230. In some embodiments, the electromagnetic energy source 230 may be, but is not limited to, a microwave energy source, an optical radiation source (e.g., laser or flash lamp), an electron beam source, and/or an ion beam source. The electromagnetic energy source 230 can be continuous or pulsed. In particular embodiments, the electromagnetic energy source 230 is a microwave energy source. The electromagnetic energy source 230 may be coupled with the chamber body 212 via a waveguide 232. The electromagnetic energy generated by the electromagnetic energy source 230 may be supplied into the processing volume 210 from a waveguide launch port 233, which is fluidly coupled with the processing volume 210 via the waveguide 232. Although FIG. 1 shows the waveguide launch port 233 disposed along the top wall 212A of the chamber body 212, the waveguide launch port 233 may also be placed in other locations such as the bottom wall 212B, the first sidewall 212C, the second sidewall 212D, or a combination of different locations.

In some embodiments, the electromagnetic energy source 230 is positioned to heat the entire substrate(s) 202. The electromagnetic energy source 230 may be positioned to deliver emitted electromagnetic energy 290 perpendicular to the major surface 203 of the substrate(s) 202 positioned on the substrate support pedestal 216. The electromagnetic energy source 230 may be a continuous or pulsed source. In particular embodiments, the electromagnetic energy source 230 is a continuous source. In particular embodiments, the electromagnetic energy source 230 is a microwave energy source (e.g., a continuous microwave energy source). In some embodiments, the emitted electromagnetic energy 290 is emitted microwaves.

In some embodiments, the electromagnetic energy source 230 is a microwave generator. The microwave generator generates a fixed frequency microwave or a variable frequency microwave. The microwave generated in the microwave generator is suppled into the processing volume 210 from the waveguide launch port 233 via the waveguide 232. In one embodiment, the frequency of microwave supplied is in a range from about 1 GHz to about 30 GHz. In another embodiment the frequency of microwave supplied is in a range from about 1 GHz to about 10 GHz, or in a range from about 2 GHz to about 6 GHz, for example, 2.45 GHz, 5.8 GHZ, etc. However, other applicable frequencies may also be used. The power of microwave may be in range from about 100 watts to about 20 kilowatts, or in a range from about 1000 watts to about 3000 watts. In one example, the microwave generator outputs 1500 watts of power at a frequency of about 2.45 GHz. In another example, the microwave generator outputs 1500 watts of power at a frequency of about 5.8 GHz. In some embodiments, the coolant medium circulation controller 260 may be connected to coolant medium circulator 240 to control the rate at which the coolant medium is circulated through the one or more channel(s) 280. In some embodiments, coolant medium circulation controller 260 determines the rate at which the coolant medium is circulated based on a substrate support temperature setpoint and a closed loop control.

In some embodiments, the closed loop control includes substrate temperature sensor 217, coolant medium circulation controller 260, and coolant medium circulator 240. For example, in some embodiments where the closed loop control is an active control, the coolant medium circulation controller 260 controls the rate at which the coolant medium is circulated.

In some embodiments, coolant medium circulation controller 260 determines the rate at which the coolant medium is circulated by using a look-up table. For example, an input key, corresponding to a microwave power value is identified and an output value corresponding to a coolant medium flow rate is used to determine the rate at which the coolant medium is circulated. In some embodiments, an input key pair, corresponding to a microwave power value and an ambient gas type present in the processing volume 210 is identified and an output value corresponding to a coolant medium flow rate is used to determine the rate at which the coolant medium is circulated. In some embodiments, the ambient gas type may be at least one of helium, nitrogen, oxygen, argon, carbon dioxide, carbon monoxide, ammonia, hydrogen sulfide, fluorine, or chlorine. In some embodiments, the coolant medium is at least one of water, liquid nitrogen, liquid helium, liquid argon, liquid oxygen, liquid neon, liquid xenon, liquid krypton, liquid carbon dioxide, liquid propane, liquid methane, ethanol, liquid freon, liquid ammonia, liquid ethylene or the like. In some embodiments, the coolant medium may be any suitable substance for use as a coolant medium.

In some embodiments, the coolant medium circulation controller 260 controls other parameters of the other parameters of the system (e.g., microwave signal output from the microwave signal generator, gas supply, exhaust rate, etc.).

In some embodiments, the processing system 200 further includes a gas supply 250. Gas supply 250 may be fluidly coupled with the processing volume via a gas inlet 252. Gas supply 250 may be coupled to the processing chamber body 212 at any suitable location for supplying gas to the processing volume 210, such as along first sidewall 212C of the chamber body 212, as illustrated. For example, depending upon chamber design and process gas flow considerations, gas inlet 252 may be located at any suitable location in the processing chamber 206, such as in the first sidewall 212C, second sidewall 212D of the processing chamber 206, above or below the surface of the substrate support pedestal 216, in the top wall 212A of the processing chamber 206, in the bottom wall 212B of the processing chamber 206, or in any other suitable location. In some embodiments, gas supply 250 may include one or more pumps and valves utilized to regulate the pressure of processing volume 210 of processing chamber 206.

In some embodiments, substrate support pedestal 216 leaves a significant portion of a surface area (e.g., major surface 203) of the substrate(s) 202 exposed to processing volume 210, and a gas is circulated within the processing volume 210 to cool the substrate(s) 202. In some embodiments, coolant medium circulation controller 260 may be connected to gas supply 250 (e.g., via a direct physical connection) to control the rate at which the gas is circulated through the processing volume 210. In some embodiments, coolant medium circulation controller 260 determines the rate at which the gas is circulated based on a substrate temperature setpoint and a closed loop control.

In some embodiments, the processing system 200 further includes the exhaust system 270. In one implementation, the exhaust system 270 is coupled to the processing chamber body 212 via an exhaust port 272. The exhaust system 270 may be coupled to the processing chamber body 212 at any suitable location for exhausting the processing volume 210, such as along the bottom wall 212B of the chamber body 212, as illustrated. For example, depending upon chamber design and process gas flow considerations, the exhaust port 272 may be located at any suitable location in the processing chamber 206, such as in the first sidewall 112C, second sidewall 112D of the processing chamber 206, above or below the surface of the substrate support pedestal 216, in the top wall 212A of the processing chamber 206, in the bottom wall 212B of the processing chamber 206, or in any other suitable location. In some embodiments, exhaust system 270 may include one or more pumps and valves utilized to evacuate and regulate the pressure of processing volume 210 of processing chamber 206.

Examples of processing gases that may be used to process substrates and/or be used as a coolant medium in processing system 200 include halogen-containing gases, such as C₂F₆, SF₆, SiCl₄, HBr, NF₃, CF₄, CHF₃, F₂, Cl₂, CCl₄, BCl₃, and SiF₄, among others, and other gases such as O₂ or N₂O. Examples of carrier gases include N₂, He, Ar, and other gases inert to process gases (e.g., non-reactive gases).

In some embodiments, coolant medium circulation controller 260 may be coupled to gas supply 250 and exhaust system 270 to control the rate at which the gas is circulated through the processing volume 210. In some embodiments, coolant medium circulation controller 260 determines the rate at which the gas is circulated (e.g., by the gas supply 250 and exhaust system 270) based on a substrate support temperature setpoint and a closed loop control.

In some embodiments, the closed loop control includes substrate temperature sensor 217, gas supply 250, exhaust system 270, and coolant medium circulation controller 260. In some embodiments, gas supply 250 and exhaust system 270 are controlled by coolant medium circulation controller 260. For example, in some embodiments where the closed loop control is an active control, the coolant medium circulation controller 260 controls the rate at which the gas is circulated (e.g., by controlling gas supply 250 and exhaust system 270). In some embodiments, coolant medium circulation controller 260 determines the rate at which the gas is circulated by using a look-up table. For example, an input key, corresponding to a microwave power value is identified and an output value corresponding to a gas flow rate is used to determine the rate at which the gas is circulated. In some embodiments, an input key pair, corresponding to a microwave power value and gas type circulating through the processing volume 210 is identified and an output value corresponding to a gas flow rate is used to determine the rate at which the gas is circulated. In some embodiments, the gas type circulating through the processing volume 210 may be at least one of helium, nitrogen, oxygen, argon, carbon dioxide, carbon monoxide, ammonia, hydrogen sulfide, fluorine, or chlorine. In some embodiments, the coolant medium is at least one of water, liquid nitrogen, liquid helium, liquid argon, liquid oxygen, liquid neon, liquid xenon, liquid krypton, liquid carbon dioxide, liquid propane, liquid methane, ethanol, liquid freon, liquid ammonia, or liquid ethylene. In some embodiments, the coolant medium may be any suitable substance for use as a coolant medium.

The gas supply 250 provides one or more suitable process gases for processing the substrate(s) 202 and/or for maintaining the processing volume 210 (such as annealing gases, deposition gases, etch gases, cleaning gases, or the like). For example, embodiments of the present disclosure may be used in annealing, deposition, or implant processes that require certain gases be provided to the processing volume 210. The gases may be reactive, such as precursors for deposition processes, or nonreactive, such as inert gases commonly used in conventional thermal processes. The processing volume 210 within which the substrate(s) 202 resides during processing may be evacuated or contain a gas suitable for the targeted process. In one implementation, the gas supply 250 comprises a plurality of gas sources supplying one or more process gases to the processing volume 210. Each process gas may be supplied independently, or in combination with additional process gases. Other components for controlling the flow of gases to the processing volume 210, such as flow controllers, valves, or the like, are, for simplicity, not shown.

In some embodiments, coolant medium circulation controller 260 may be coupled with other components of processing system 200 (e.g., coolant medium circulator 240, temperature sensor 217, gas supply 250, exhaust system 270, electromagnetic energy source 230, etc.) via any suitable connection type. For example, coolant medium circulation controller 260 may be coupled with the above listed components of processing system 200 via a network (e.g., local area network (LAN), wide area network (WAN), etc.), a bus connection (e.g., a shared data bus, a serial bus, etc.), a wireless connection (e.g., via Wi-Fi, Bluetooth, etc.), a direct connection (e.g., wired connection), an optical connection, an RF connection, etc.

In some embodiments, the processing system 200 further includes the coolant medium circulation controller 260 operable to facilitate control and automation of various aspects of the microwave annealing for low thermal budget applications techniques, for example, the methods 300A and 300B, and the processing system 200. The coolant medium circulation controller 260 facilitates the control and automation of the processing system 200 and can include a central processing unit (CPU), memory, and support circuits (or I/O). The CPU may be one of any form of computer processors that are used in industrial settings for controlling various processes and hardware (e.g., conventional electromagnetic radiation detectors, motors, temperature measurement hardware, microwave hardware, etc.) and monitor the processes (e.g., substrate temperature, substrate support temperature, amount of energy from the microwave source, coolant medium flow rate (e.g., gas flow rate), etc.). Software instructions and data can be coded and stored within the memory for instructing the CPU. The coolant medium circulation controller 260 can communicate with one or more of the components of the processing system 200 via, for example, a system bus. A program (or computer instructions) readable by the coolant medium circulation controller 260 determines which tasks are performable on a substrate. In some embodiments, the program is software readable by the controller and includes code to monitor and control the substrate position, the amount of energy delivered in the continuous electromagnetic energy emitted, the amount of energy delivered in each electromagnetic pulse, the intensity and wavelength as a function of time for each pulse, the temperature of various regions of the substrate, or any combination thereof. Although the coolant medium circulation controller 260 is shown as a single coolant medium circulation controller, it should be appreciated that multiple coolant medium circulation controllers can be used with the embodiments described herein.

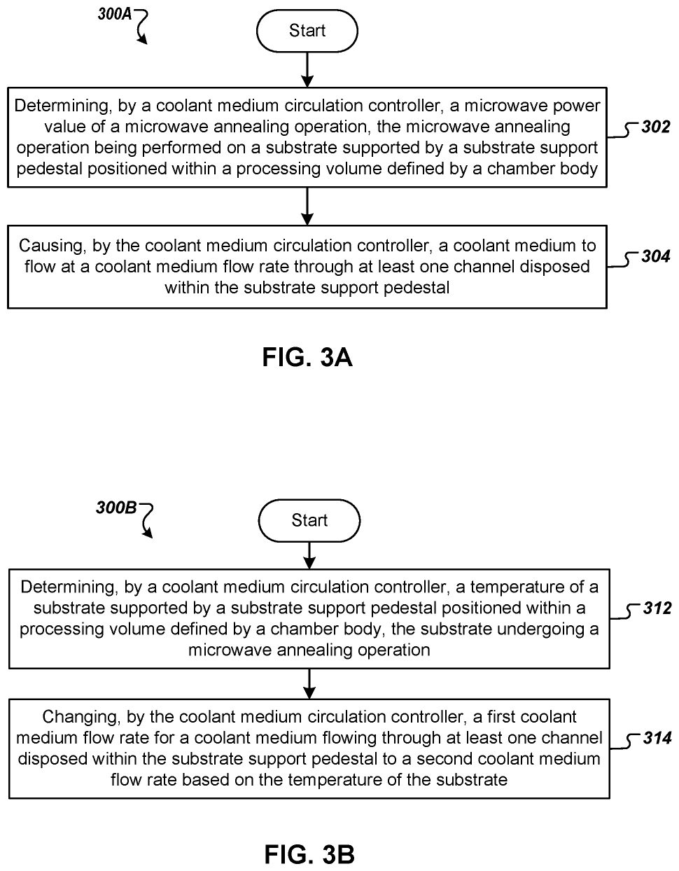

FIGS. 3A-B are flow diagrams of methods 300A-B associated with microwave annealing for low thermal budget applications, according to certain embodiments. Methods 300A-B may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiment, methods 300A-B may be performed, in part, by processing system 200. In some embodiments, a non-transitory storage medium stores instructions that when executed by a processing device (e.g., of processing system, of) cause the processing device to perform one or more of methods 300A-B.

For simplicity of explanation, methods 300A-B are depicted and described as a series of operations. However, operations in accordance with this disclosure can occur in various orders and/or concurrently and with other operations not presented and described herein. Furthermore, not all illustrated operations may be performed to implement methods 300A-B in accordance with the disclosed subject matter. In addition, those skilled in the art will understand and appreciate that methods 300A-B could alternatively be represented as a series of interrelated states via a state diagram or events.

FIG. 3A is a flow diagram of a method 300A for microwave annealing for low thermal budget applications, according to certain embodiments.

Referring to FIG. 3A, in some embodiments, at block 302 the processing logic implementing method 300A determines, by a coolant medium circulation controller, a microwave power value of a microwave annealing operation, the microwave annealing operation being performed on a substrate supported by a substrate support pedestal positioned within a processing volume defined by a chamber body.

At block 304, processing logic causes, by the coolant medium circulation controller, a coolant medium to flow at a coolant medium flow rate through at least one channel disposed within the substrate support pedestal.

In some embodiments, the coolant medium flow rate may be determined using a look-up table. In some embodiments a look-up table may be a data structure, or a mathematical function used to quickly retrieve pre-calculated values (e.g., output vales) based on input parameters (e.g., input key values, input key value pairs, etc.). In some embodiments, the look-up table includes input key values each corresponding to a respective microwave power value and output values each corresponding to a respective coolant medium flow rate.

In some embodiments, the look-up table includes input key value pairs output values. In some embodiments, the input key value pairs each correspond to a respective microwave power value and a respective ambient gas type in the processing volume. In some embodiments, the output values each correspond to a respective coolant medium flow rate.

In some embodiments, the respective ambient gas type may be at least one of helium, nitrogen, oxygen, argon, carbon dioxide, carbon monoxide, ammonia, hydrogen sulfide, fluorine, or chlorine. In some embodiments, the coolant medium is at least one of water, liquid nitrogen, liquid helium, liquid argon, liquid oxygen, liquid neon, liquid xenon, liquid krypton, liquid carbon dioxide, liquid propane, liquid methane, ethanol, liquid freon, liquid ammonia, or liquid ethylene. In some embodiments, the coolant medium may be any substance suitable for use as a coolant medium.

In some embodiments, a wavelength of microwaves of the microwave annealing operation may range from two gigahertz to seven gigahertz.

In some embodiments, the microwave power value of the microwave annealing operation may range from 100 watts to 20 kilowatts.

FIG. 3B is a method 300B for microwave annealing for low thermal budget applications, according to some embodiments.

Referring to FIG. 3B, at block 312 of method 300B, the processing logic determines, by a coolant medium circulation controller, a temperature of a substrate supported by a substrate support pedestal positioned within a processing volume defined by a chamber body, the substrate undergoing a microwave annealing operation.

In some embodiments, the temperature of a substrate undergoing the microwave annealing operation may be determined using a substrate temperature sensor. The temperature of the substrate undergoing the microwave annealing operation as measured by the substrate temperature sensor may be communicated to the coolant medium circulation controller.

In some embodiments, a wavelength of microwaves of the microwave annealing operation may range from two gigahertz to seven gigahertz.

At block 314, the processing logic changes, by the coolant medium circulation controller, a first coolant medium flow rate for a coolant medium flowing through at least one channel disposed within the substrate support pedestal to a second coolant medium flow rate based on the temperature of the substrate. In some embodiments, such a change in the coolant medium flow rate may correspond to either and increase or a decrease in the coolant medium flow rate.

In some embodiments, the at least one channel may facilitate heat transfer from the substrate to the coolant medium.

In some embodiments, the substrate support pedestal may leave a significant portion of a surface area of the substrate exposed to the processing volume. In some embodiments, the coolant medium may include a gas that is circulated within the processing volume to cool the substrate.

In some embodiments, the substrate support pedestal may be at least one of a susceptor, edge ring (e.g., a component surrounding the periphery of the wafer and providing mechanical support and protection during processing), electrostatic chuck (e.g., used for wafer clamping in semiconductor processing using an electrostatic force to hold the wafer in place on a flat surface), mechanical clamp (e.g., a set of arms or jaws hold the wafer in place using a mechanical force), vacuum chuck (e.g., a vacuum holds the wafer in place against a flat surface), pin chuck (e.g., a set of small pins that extend through the backside of the wafer to hold it in place against a flat surface), magnetic chuck (e.g., magnetic force to holds the wafer in place against a flat surface), tape/adhesive (e.g., a specialized tape and/or adhesive holds a wafer in place), etc.

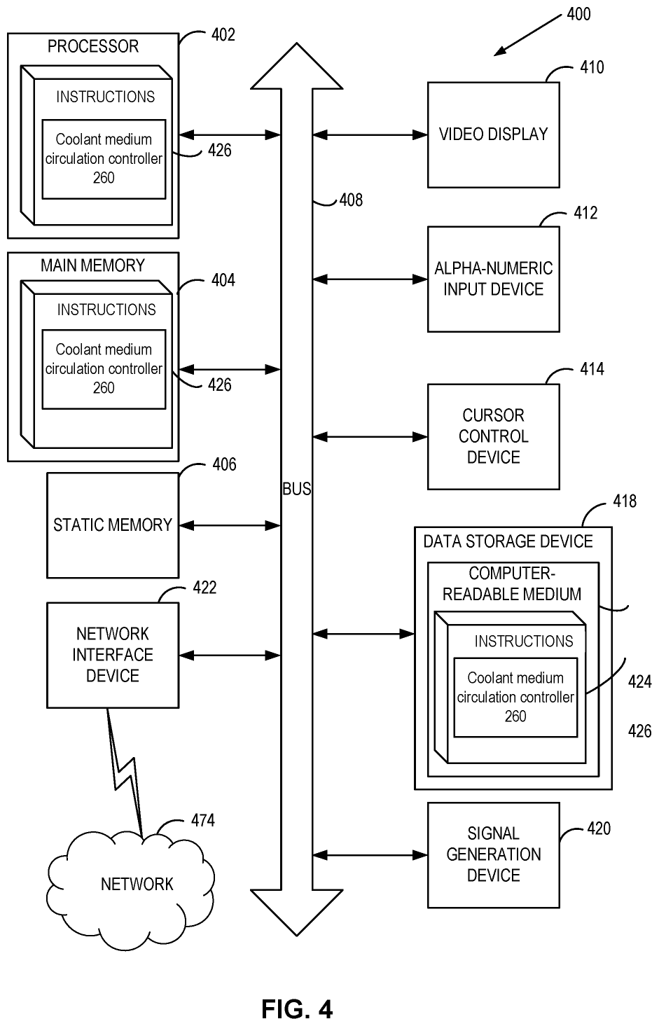

FIG. 4 is a block diagram illustrating a computer system 400, according to certain embodiments. In some embodiments, computer system 400 may be connected (e.g., via a network, such as a Local Area Network (LAN), an intranet, an extranet, or the Internet) to other computer systems. Computer system 400 may operate in the capacity of a server or a client computer in a client-server environment, or as a peer computer in a peer-to-peer or distributed network environment. Computer system 400 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 400 may include a processing device 402, a volatile memory 404 (e.g., Random Access Memory (RAM)), a non-volatile memory 406 (e.g., Read-Only Memory (ROM) or Electrically-Erasable Programmable ROM (EEPROM)), and a data storage device 418, which may communicate with each other via a bus 408.

Processing device 402 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 400 may further include a network interface device 422 (e.g., coupled to network 474). Computer system 400 also may include a video display unit 410 (e.g., an LCD), an alphanumeric input device 412 (e.g., a keyboard), a cursor control device 414 (e.g., a mouse), and a signal generation device 420.

In some implementations, data storage device 418 may include a non-transitory computer-readable storage medium 424 (e.g., non-transitory machine-readable storage medium) on which may store instructions 426 encoding any one or more of the methods or functions described herein, including instructions encoding components of FIG. 1 and FIG. 2 (e.g., system controller 128, coolant medium circulation controller 260, etc.) and for implementing methods described herein.

Instructions 426 may also reside, completely or partially, within volatile memory 404 and/or within processing device 402 during execution thereof by computer system 400, hence, volatile memory 404 and processing device 402 may also constitute machine-readable storage media.

While computer-readable storage medium 424 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “determining,” “causing,” “changing,” “receiving,” “performing,” “providing,” “obtaining,” “accessing,” “adding,” “using,” “training,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A system comprising:
a chamber body defining a processing volume;
a substrate support pedestal positioned in the processing volume and operable to support a substrate, the substrate support pedestal comprising one or more channels, wherein a coolant medium flows through the one or more channels to facilitate heat transfer from the substrate to the coolant medium;
a coolant medium circulator to circulate the coolant medium through the one or more channels;
a substrate temperature sensor operatively coupled to the chamber body, wherein the substrate temperature sensor measures a temperature of the substrate; and
a coolant medium circulation controller, coupled to the coolant medium circulator and the substrate temperature sensor, to control a rate at which the coolant medium is circulated through the one or more channels.

2. The system of claim 1, wherein the substrate receives microwaves during a microwave annealing operation.

3. The system of claim 2, wherein a wavelength of the microwaves of the microwave annealing operation ranges from two gigahertz to seven gigahertz.

4. The system of claim 1, wherein the coolant medium circulation controller determines the rate at which the coolant medium is circulated based on a substrate support temperature setpoint and a closed loop control, the closed loop control comprising:
the substrate temperature sensor;
the coolant medium circulation controller; and
the coolant medium circulator.

5. The system of claim 1, wherein the coolant medium circulation controller determines the rate at which the coolant medium is circulated by using a look-up table.

6. The system of claim 5, wherein the look-up table comprises:
input key values each corresponding to a respective microwave power value; and
output values each corresponding to a respective coolant medium flow rate.

7. The system of claim 5, wherein the look-up table comprises:
input key value pairs, wherein each of the input key value pairs corresponds to a respective microwave power value and a respective ambient gas type in the processing volume; and
output values each corresponding to a respective coolant medium flow rate.

8. The system of claim 7, wherein the respective microwave power value ranges from 100 watts to 20 kilowatts, the respective ambient gas type is at least one of helium, nitrogen, oxygen, argon, carbon dioxide, carbon monoxide, ammonia, hydrogen sulfide, fluorine, or chlorine, and the coolant medium is at least one of water, liquid nitrogen, liquid helium, liquid argon, liquid oxygen, liquid neon, liquid xenon, liquid krypton, liquid carbon dioxide, liquid propane, liquid methane, ethanol, liquid freon, liquid ammonia, or liquid ethylene.

9. The system of claim 1, wherein the substrate support pedestal leaves a significant portion of a surface area of the substrate exposed to the processing volume, and wherein a gas is circulated within the processing volume to cool the substrate.

10. A method comprising:
determining, by a coolant medium circulation controller, a microwave power value of a microwave annealing operation, the microwave annealing operation being performed on a substrate supported by a substrate support pedestal positioned within a processing volume defined by a chamber body; and
causing, by the coolant medium circulation controller, a coolant medium to flow at a coolant medium flow rate through at least one channel disposed within the substrate support pedestal.

11. The method of claim 10, wherein the coolant medium flow rate is determined using a look-up table, the look-up table comprising:
input key values each corresponding to a respective microwave power value; and
output values each corresponding to a respective coolant medium flow rate.

12. The method of claim 10, wherein the coolant medium flow rate is determined using a look-up table, the look-up table comprising:
input key value pairs, wherein each of the input key value pairs corresponds to a respective microwave power value and a respective ambient gas type in the processing volume; and
output values each corresponding to a respective coolant medium flow rate.

13. The method of claim 12, wherein the respective ambient gas type is at least one of helium, nitrogen, oxygen, argon, carbon dioxide, carbon monoxide, ammonia, hydrogen sulfide, fluorine, or chlorine.

14. The method of claim 10, wherein a wavelength of microwaves of the microwave annealing operation ranges from two gigahertz to seven gigahertz.

15. The method of claim 10, wherein the microwave power value of the microwave annealing operation ranges from 100 watts to 20 kilowatts.

16. A method comprising:
determining, by a coolant medium circulation controller, a temperature of a substrate supported by a substrate support pedestal positioned within a processing volume defined by a chamber body, the substrate undergoing a microwave annealing operation; and
changing, by the coolant medium circulation controller, a first coolant medium flow rate for a coolant medium flowing through at least one channel disposed within the substrate support pedestal to a second coolant medium flow rate based on the temperature of the substrate.

17. The method of claim 16, wherein the temperature of a substrate undergoing the microwave annealing operation is determined using a substrate temperature sensor.

18. The method of claim 16, wherein the at least one channel facilitates heat transfer from the substrate to the coolant medium.

19. The method of claim 16, wherein the substrate support pedestal leaves a significant portion of a surface area of the substrate exposed to the processing volume, and wherein the coolant medium comprises a gas that is circulated within the processing volume to cool the substrate.

20. The method of claim 16, wherein a wavelength of microwaves of the microwave annealing operation ranges from two gigahertz to seven gigahertz.
